(19) United States
(12) Patent Application Publication
(10) Pub. No.: US 2026/0085079 A1
(43) Pub. Date: Mar. 26, 2026

(54) COMPOSITION FOR LOW-DIELECTRIC FILM, LOW-DIELECTRIC FILM AND MANUFACTURING METHOD THEREOF

(71) Applicants: Samsung Electronics Co., Ltd., Suwon-si (KR); DNF Co., Ltd., Daejeon (KR)

(72) Inventors: Donghun Jung, Suwon-si (KR); Gun Joo Park, Daejeon (KR); In Kyung Jung, Daejeon (KR); Sunhye Hwang, Suwon-si (KR); Min Sung Kim, Suwon-si (KR); Sung Gi Kim, Daejeon (KR); Jeong Joo Park, Daejeon (KR); Se Jin Jang, Daejeon (KR); Cheol Won Jung, Daejeon (KR); Byungkeun Hwang, Suwon-si (KR)

(21) Appl. No.: 19/078,335

(22) Filed: Mar. 13, 2025

(30) Foreign Application Priority Data
Sep. 25, 2024 (KR) 10-2024-0129858

(51) Int. Cl. C07F 7/18; C23C 16/24; C23C 16/448; C23C 16/452

(52) U.S. Cl. CPC C07F 7/1804; C23C 16/24; C23C 16/4481; C23C 16/452

(57) ABSTRACT

A composition for forming a low-dielectric film, comprising a silicon precursor comprising a *—Si—C—Si—* bond and having a ratio of *—Si—C—Si—* bond unit to *—Si—O—* bond unit ratio of 0.1 to 0.8, the low-dielectric film, and the low-dielectric film manufacturing method are provided. A low-dielectric film manufactured using the composition of the present disclosure can implement a low-dielectric film with very high resistance to plasma damage, which could not be implemented using conventional compositions for forming low-dielectric films.

### CROSS-REFERENCE TO RELATED APPLICATION

This application claims priority to and the benefit of Korean Patent Application No. 10-2024-0129858, filed on Sep. 25, 2024, in the Korean Intellectual Property Office, the entire contents of which are incorporated herein by reference.

### BACKGROUND OF THE INVENTION

### (a) Field of the Invention

The present disclosure relates to composition for forming a low-dielectric film, a low-dielectric film, and a manufacturing method thereof.

### (b) Description of the Related Art

Semiconductor devices are widely used in the electronics industry due to their characteristics such as miniaturization, multi-functionality and low manufacturing cost. Semiconductor devices may include memory devices storing data, logic devices operating data, and hybrid devices capable of performing various functions simultaneously.

As the electronics industry progresses rapidly, the demand for higher integration of semiconductor devices is further increased. Accordingly, various problems, such as a decrease in the process margin of the photolithography process defining fine patterns, occur, which makes the implementation of semiconductor devices more and more difficult. Also, due to the progress of the electronics industry, the demand for higher speed semiconductor devices is increased. To meet the demands for higher integration and/or higher speed of these semiconductor devices, various studies are being conducted.

In particular, as semiconductor devices become extremely miniaturized, the need for low-dielectric films to maintain resistive-capacitive (RC) delay characteristics increases. Also, dielectric constant degradation and pattern profile degradation occur due to plasma damage during the subsequent patterning etching process, which results in RC delay and reliability degradation. The development of a technology that maintains excellent mechanical characteristics and resistance to plasma damage while having low dielectric characteristics remains to be solved.

### SUMMARY OF THE INVENTION

An aspect of the present disclosure is forming a low-dielectric film having a ratio of *—Si—C—Si—* bond unit to *—Si—O—* bond unit by use of a composition comprising a silicon precursor controlled with a specific structure. The low-dielectric film, different from the conventional dielectric film, has a high elastic coefficient and very excellent plasma damage resistance that meet low PID (Plasma Induced Damage) characteristics. Additionally, the low-dielectric film can be easily deposited even at small pitches of several tens of nanometers in size. That is, the present disclosure provides a novel precursor structure for low-dielectric film having a high ratio of *—Si—C—Si—* bonds to provide a low-dielectric film having high plasma damage resistance which the conventional low dielectric precursor, such as silica, could not achieve, and to provide a method of depositing the same.

A composition for forming a low-dielectric film according to an aspect is for forming a low-dielectric film having a ratio of *—Si—C—Si—* bond unit to *—Si—O—* bond unit (*—Si—C—Si—* bond unit/*—Si—O—* bond unit) of 0.1 to 0.8, for example 0.1 to 0.4, and comprises a silicon precursor comprising a *—Si—C—Si—* bond.

In some embodiments, the silicon precursor may be represented by the following chemical formula 1.

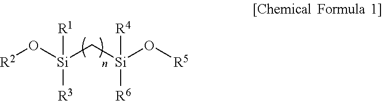

In formula 1 above,
each of R¹, R³, R⁴ and R⁶ is independently hydrogen atom, substituted or unsubstituted C¹ to C²⁰ alkyl group, substituted or unsubstituted C¹ to C²⁰ alkoxy group, substituted or unsubstituted C³ to C²⁰ cycloalkyl group, substituted or unsubstituted C² to C²⁰ alkenyl group, substituted or unsubstituted C² to C²⁰ alkynyl group, substituted or unsubstituted C³ to C²⁰ cycloalkenyl group, substituted or unsubstituted C⁵ to C²⁰ cycloalkynyl group, substituted or unsubstituted C⁶ to C²⁰ aryl group or substituted or unsubstituted C⁶ to C²⁰ aryloxy group.
each of R² and R⁵ is and independently substituted or unsubstituted C¹ to C²⁰ alkyl group, substituted or unsubstituted C³ to C²⁰ cycloalkyl group, substituted or unsubstituted C² to C²⁰ alkenyl group, substituted or unsubstituted C² to C²⁰ alkynyl group, substituted or unsubstituted C³ to C²⁰ cycloalkenyl group or substituted or unsubstituted C⁶ to C²⁰ aryl group, and n is an integer from 1 to 4.

In some embodiments, the silicon precursor may be represented by the following chemical formula 2.

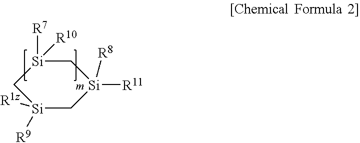

In formula 2,
each of R⁷ to R¹² is independently hydrogen atom, substituted or unsubstituted C¹ to C²⁰ alkyl group, substituted or unsubstituted C¹ to C²⁰ alkoxy group, substituted or unsubstituted C³ to C²⁰ cycloalkyl group, substituted or unsubstituted C² to C²⁰ alkenyl group, substituted or unsubstituted C² to C²⁰ alkynyl group, substituted or unsubstituted C³ to C²⁰ cycloalkenyl group, substituted or unsubstituted C⁶ to C²⁰ aryl group or substituted or unsubstituted C⁶ to C²⁰ aryloxy group, and m is an integer from 1 to 5.

In some embodiments, in chemical formula 1, at least one of R¹ to R³ may be a substituted or unsubstituted C¹ to C²⁰ alkoxy group.

In some embodiments, in chemical formula 1, R¹ may be a substituted or unsubstituted C¹ to C²⁰ alkoxy group, each of R² to R⁶ may be independently substituted or unsubstituted C¹ to C²⁰ alkyl groups, and n may be 1.

In some embodiments, in chemical formula 2, each of R⁷ to R⁹ is independently a hydrogen atom or a substituted or unsubstituted C¹ to C²⁰ alkyl group, each of R¹⁰ to R¹² is independently substituted or unsubstituted C¹ to C²⁰ alkoxy group, and m may be 1.

In some embodiments, the low-dielectric film according to an aspect includes a silicon precursor comprising *—Si—C—Si—* bonds, and the ratio of *—Si—C—Si—* bond unit to *—Si—O—* bond unit (*—Si—C—Si—* bond unit/*—Si—O—* bond unit) in the film may be 0.1 to 0.8, for example 0.1 to 0.4.

In some embodiments, the content of carbon in the dielectric layer may be 10 at % to 50 at %, for example 31 at % to 40 at %.

In some embodiments, the ratio of *—Si—C—Si—* bond unit to *—Si—O—* bond unit (*—Si—C—Si—* bond unit/*—Si—O—* bond unit) of the low-dielectric film may be 0.1 to 0.2.

In some embodiments, the dielectric layer may have a dielectric constant of 2.5 to 3, for example, 2.8 or more and 3 or less.

In some embodiments, the dielectric layer may have an elasticity coefficient of 8 GPa to 15 GPa, for example, 10 Gpa to 15 Gpa.

In some embodiments, the dielectric layer may include pores.

According to an aspect, a manufacturing method of low-dielectric film having a ratio of *—Si—C—Si—* bond unit to *—Si—O—* bond unit (*—Si—C—Si—* bond unit/*—Si—O—* bond unit) of 0.1 to 0.8, for example 0.1 to 0.4, includes: preparing a base; and depositing a silicon precursor including *—Si—C—Si—* bonding on the base.

In some embodiments, the ratio of *—Si—C—Si—* bond unit to *—Si—O—* bond unit (*—Si—C—Si—* bond unit/*—Si—O—* bond unit) of the low dielectric film may be 0.1 to 0.2.

In some embodiments, the deposition may be performed by atomic layer deposition, metal-organic chemical vapor deposition, low pressure vapor deposition, plasma enhanced chemical vapor deposition, plasma enhanced atomic layer deposition, VHF (Very High Frequency) chemical vapor deposition, or initiated chemical vapor deposition (iCVD).

In some embodiments, the deposition may be performed by a plasma enhanced chemical vapor deposition method.

In some embodiments, the low-dielectric film manufacturing method may further include forming a low-dielectric film by depositing the silicon precursor, and then patterning the low-dielectric film for metal deposition.

In some embodiments, the pitch formed after the patterning may be 100 nm or less.

In some embodiments, the silicon precursor may contain at least one of the following chemical formula E-1 to chemical formula E-8.

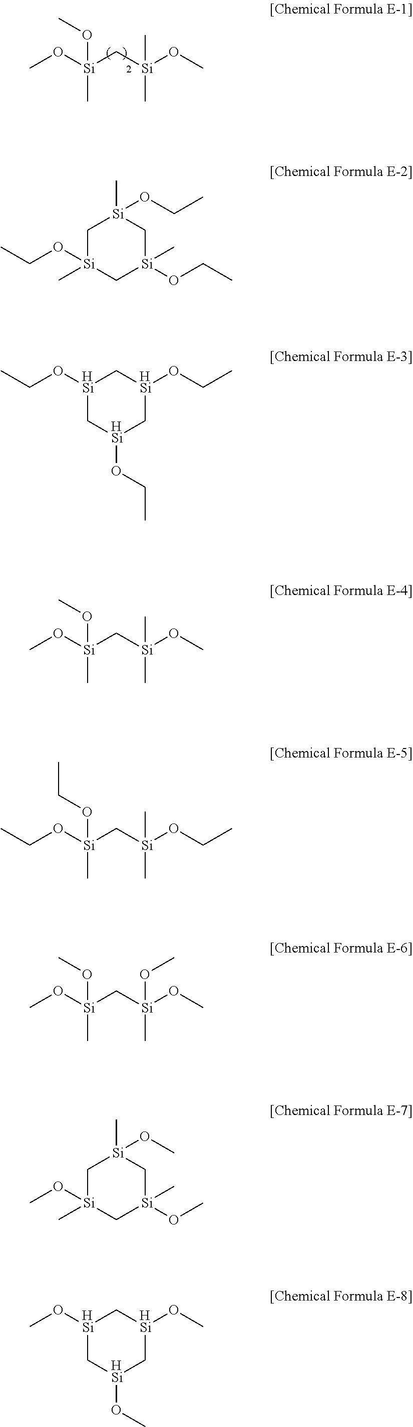

A composition for forming a low-dielectric film including a silicon precursor including a *—Si—C—Si—* bond according to one aspect may form a low-dielectric film having a ratio of *—Si—C—Si—* bond unit to *—Si—O—* bond unit (*—Si—C—Si—* bond unit/*—Si—O—* bond unit) of 0.1 to 0.8, for example 0.1 to 0.4, and the low-dielectric film may satisfy a high elasticity coefficient and a low PID (plasma induced damage) characteristic simultaneously.

### BRIEF DESCRIPTION OF THE DRAWINGS

FIG. 1 is a drawing sequentially illustrating a low-dielectric film manufacturing method according to one aspect.

FIG. 2 is a schematic view of the degraded portion of the film surface damaged by plasma during a subsequent metal patterning process after depositing a low-dielectric film using a composition for forming a low-dielectric film including a precursor (Chemical Formula E-3) according to one aspect and a composition for forming a low-dielectric film including silica that is a conventional precursor.

### DETAILED DESCRIPTION OF THE EMBODIMENTS

Hereinafter, with reference to accompanying drawings, various embodiments of the present disclosure will be described in detail so that a person of an ordinary skill can easily implement the present disclosure. The present disclosure may be implemented in many different forms and is not limited to the embodiments described herein.

In order to clearly explain the present disclosure, parts that are not relevant to the description are omitted, and identical or similar components are assigned the same reference numerals throughout the specification.

In addition, the size and thickness of each component shown in the drawings are shown arbitrarily for convenience of explanation, so the present disclosure is not necessarily limited to what is shown. In the drawings, the thickness of layers, films, panels, regions, etc., are exaggerated for clarity. And in the drawings, for convenience of explanation, the thicknesses of some layers and regions are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, being “on” or “above” a reference element means being positioned on or below the reference element, and does not necessarily mean being positioned “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

In addition, throughout the specification, when referring to “a plane view”, it means that the target portion is viewed from above, and when referring to “a cross-section view”, it means that a cross section of the target portion cut vertically is viewed from a side.

Additionally, throughout the specification, “low-dielectric film” means a dielectric layer with a dielectric constant of 3 or less.

The present disclosure relates to a low-dielectric film capable of improving PID characteristics, the film having increased *—Si—C—Si—* bond content of a final deposition film by including *—Si—C—Si—* bond with a high ratio in the precursor structure, a composition for forming the low-dielectric film, and a manufacturing method of the low-dielectric film. Specifically, the low-dielectric film has a ratio of *—Si—C—Si—* bond unit to *—Si—O—* bond unit (*—Si—C—Si—* bond unit/*—Si—O—* bond unit) of 0.1 to 0.8, for example 0.1 to 0.4, and the composition for forming the low-dielectric film includes a silicon precursor comprising *—Si—C—Si—* bonds. Since the low-dielectric film according to the present disclosure has characteristics as described above, when wirings are formed inside the low-dielectric film, the wirings can be supported with high mechanical strength of the low-dielectric film. Additionally, the capacitance between the wirings can be reduced since the low-dielectric film has a dielectric constant, in some embodiments, of 2.5 to 3, for example 2.8 to 3.

In the past, there were attempts to improve the PID characteristics by improving the crosslinking characteristics in the dielectric layer which is the final deposition film, but it has never been studied whether the PID characteristics of the dielectric layer which is the final deposition film can be maximized by controlling the structure of the precursor that forms the dielectric layer which is the final deposition film.

Since the ultimate desired property of film is a low-dielectric with high plasma damage resistance, the present inventors identified an appropriate precursor structure that could implement this, and after various attempts, confirmed that the *—Si—C—Si—* bond is an important bond to improve PID, designed and evaluated various structures that improved the relative ratio of *—Si—C—Si—* bond within the silicon precursor structure in order to increase the *—Si—C—Si—* bond content in dielectric film which is the final film, and finally completed the present disclosure. As a result, it was experimentally confirmed that as the ratio of *—Si—C—Si—* bonds to Si atoms (*—Si—C—Si—* bonds/Si atoms) in the silicon precursor structure, which is an active ingredient in the composition for forming the low-dielectric film, increases, the ratio of *—Si—C—Si—* bonds to Si atoms in the dielectric layer which is the deposition film also increases, and the PID characteristics are also improved. Since it has never been suggested that PID improvement effects can be achieved by controlling the bonding ratio in the silicon precursor structure, as described above, so far, the present disclosure is clearly differentiated from the conventional art.

As the pattern pitch decreases, the ratio of the surface affected by plasma among the entire low-dielectric film increases, so resistance to plasma is important. The goal of the present disclosure is to provide a structure that can minimize the total effective k degradation, including the plasma damage region after the subsequent patterning process, by designing at precursor structure stage to have high resistance to the plasma, and to implement a low-dielectric film with high resistance to plasma that could not be implemented with conventional materials.

The present disclosure proposes a precursor structure capable of forming a large amount of *—Si—C—Si—* bonds in a low-dielectric film. On the other hand, while some *—Si—C—Si—* bonds can be formed through recombination of hydrocarbon species broken by plasma during the deposition process even if *—Si—C—Si—* bonds are not present in the precursor structure, it is difficult to expect an effect that many *—Si—C—Si—* bonds are formed in the low-dielectric film which is the final deposition film to improve PID.

A silicon precursor according to one aspect including *—Si—C—Si—* bonds in a composition for forming a low-dielectric film which has a ratio of *—Si—C—Si—* bond unit to *—Si—O—* bond unit ratio (*—Si—C—Si—* bond unit/*—Si—O—* bond unit) of 0.1 to 0.8, for example 0.1 to 0.4, may be represented by the following chemical formula 1 or chemical formula 2.

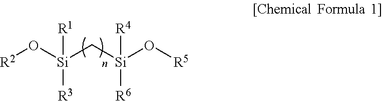

In formula 1,
each of R¹, R³, R⁴ and R⁶ is independently hydrogen atom, substituted or unsubstituted C¹ to C²⁰ alkyl group, substituted or unsubstituted C¹ to C²⁰ alkoxy group, substituted or unsubstituted C³ to C²⁰ cycloalkyl group, substituted or unsubstituted C² to C²⁰ alkenyl group, substituted or unsubstituted C² to C²⁰ alkynyl group, substituted or unsubstituted C³ to C²⁰ cycloalkenyl group, substituted or unsubstituted C⁵ to C²⁰ cycloalkynyl group, substituted or unsubstituted C⁶ to C²⁰ aryl group or substituted or unsubstituted C⁶ to C²⁰ aryloxy group,
each of R² and R⁵ is independently substituted or unsubstituted C¹ to C²⁰ alkyl group, substituted or unsubstituted C³ to C²⁰ cycloalkyl group, substituted or unsubstituted C² to C²⁰ alkenyl group, substituted or unsubstituted C² to C²⁰ alkynyl group, substituted or unsubstituted C³ to C²⁰ cycloalkenyl group or substituted or unsubstituted C⁶ to C²⁰ aryl group, and
n is an integer from 1 to 4.

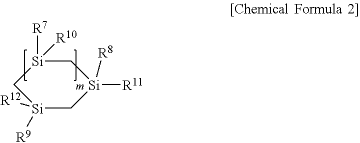

In chemical formula 2,
each of R⁷ to R¹² is independently hydrogen atom, substituted or unsubstituted C¹ to C²⁰ alkyl group, substituted or unsubstituted C¹ to C²⁰ alkoxy group, substituted or unsubstituted C³ to C²⁰ cycloalkyl group, substituted or unsubstituted C² to C²⁰ alkenyl group, substituted or unsubstituted C² to C²⁰ alkynyl group, substituted or unsubstituted C³ to C²⁰ cycloalkenyl group, substituted or unsubstituted C⁶ to C²⁰ aryl group or substituted or unsubstituted C⁶ to C²⁰ aryloxy group, and m is an integer from 1 to 5.

In some embodiments, in chemical formula 1, at least one of R¹ to R³ may be a substituted or unsubstituted C¹ to C²⁰ alkoxy group.

In some embodiments, in chemical formula 1, R¹ may be a substituted or unsubstituted C¹ to C²⁰ alkoxy group, each of R² to R⁶ may be independently substituted or unsubstituted C¹ to C²⁰ alkyl groups, and n may be an integer of 1.

In some embodiments, in chemical formula 2, each of R¹⁰ to R¹² may be independently substituted or unsubstituted C¹ to C²⁰ alkoxy group.

In some embodiments, in chemical formula 2, each of R⁷ to R⁹ may be independently a hydrogen atom or a substituted or unsubstituted C¹ to C²⁰ alkyl group, and m may be 1.

In some embodiments, the compound represented by chemical formula 1 or chemical formula 2 may have a molecular weight of 100 g/mol to 500 g/mol.

In some embodiments, the silicon precursor in the composition for forming a low-dielectric film according to one aspect may have a ratio of *—Si—C—Si—* bonds to Si atoms (*—Si—C—Si—* bonds/Si) of 0.5 or more, for example 0.5 to 1, and specifically may be 1.

In some embodiments, in chemical formula 1, it may be easier to implement the aforementioned effect when n is 1 than when n is an integer from 2 to 4. In the *—Si—C—Si—* bond, the C having one carbon atom may be much more advantageous in implementing low-dielectric characteristics than having two or more carbon atoms.

For example, “in chemical formula 1, a compound where R¹ is a substituted or unsubstituted C¹ to C²⁰ alkoxy group, each of R² to R⁶ is independently substituted or unsubstituted C¹ to C²⁰ alkyl groups, and n is 1” and “in chemical formula 2, a compound where each of R⁷ to R⁹ is independently substituted or unsubstituted C¹ to C²⁰ alkyl groups, each of R¹⁰ to R¹² is independently substituted or unsubstituted C¹ to C²⁰ alkoxy groups, and m is 1” can easily implement the aforementioned effects compared to other compounds, and a compound represented by chemical formula 2 can implement the aforementioned effects more easily than a compound represented by chemical formula 1. Since the compound represented by the chemical formula 2 unconditionally has one carbon atom in the *—Si—C—Si—* bond, and, further, has a ring structure, it is excellent in resistance to plasma damage and very advantageous in implementing low-dielectric characteristics.

The low-dielectric film according to an aspect includes a silicon precursor including a *—Si—C—Si—* bond, and a ratio of *—Si—C—Si—* bond unit to *—Si—O—* bond unit (*—Si—C—Si—* bond unit/*—Si—O—* bond unit) is 0.1 to 0.8, for example 0.1 to 0.7, for example 0.1 to 0.6, for example 0.1 to 0.5, for example 0.1 to 0.4, specifically, the ratio of *—Si—C—Si—* bond unit to *—Si—O—* bond unit is 0.1 to 0.2, more specifically, the ratio of *—Si—C—Si—* bond unit to *—Si—O—* bond unit ratio may be 0.12 to 0.2, for example 0.13 to 0.2, for example 0.14 to 0.2.

In some embodiments, the carbon content in the low-dielectric film may be 10 at % to 50 at %, for example 15 at % to 45 at %, for example 20 at % to 44 at %, for example 25 at % to 43 at %, for example 26 at % to 42 at %, for example 31 at % to 40 at %, and the dielectric constant of the low-dielectric film may be 2.5 to 3, for example 2.6 to 3, for example 2.7 to 3, for example 2.8 to 3, and an elasticity coefficient of the low-dielectric film may be 8 GPa to 15 GPa, for example 9 GPa to 15 GPa, for example 10 Gpa to 15 GPa, since the ratio of *—Si—C—Si—* bond unit to *—Si—O—* bond unit (*—Si—C—Si—* bond unit/*—Si—O—* bond unit) in the low-dielectric film has the above range. The carbon content and elasticity coefficient of the above range are both higher than those of conventional low-dielectric film, which can implement a low-dielectric film with highly improved resistance to plasma damage and excellent mechanical strength simultaneously.

In some embodiments, the dielectric layer may include pores. That is, the dielectric layer may be a porous thin film. Since the low-dielectric film includes pores, damage to the low-dielectric film caused by plasma can be reduced during the patterning process for metal deposition described later. That is, plasma induced damage can be improved.

In some embodiments, the porosity of the dielectric layer can be 8% to 35%. In other words, the sum of the volume of the pores in the low-dielectric film may be 8% to 35% of the entire volume of the low-dielectric film. In some embodiments, the average diameter of the pores in the dielectric layer may be 0.5 nm to 5 nm. In some embodiments, the pore size (diameter) distribution of the dielectric layer may be 0.1 nm to 2.5 nm. In other words, in the distribution curve of the pore size (diameter), its full width at half maximum may be from 0.1 nm to 2.5 nm.

According to one aspect, a method of manufacturing low-dielectric film where a ratio of *—Si—C—Si—* bond unit to *—Si—O—* bond unit (*—Si—C—Si—* bond unit/*—Si—O—* bond unit) is 0.1 to 0.8, for example 0.1 to 0.7, for example 0.1 to 0.6, for example 0.1 to 0.5, for example 0.1 to 0.4, specifically 0.1 to 0.2, includes preparing a base; and depositing a silicon precursor including *—Si—C—Si—* bonding on the base.

In some embodiments, the dielectric layer may be formed through a deposition process using the silicon precursor as a source gas. At this time, the deposition process may include, without limitation, atomic layer deposition, metal-organic chemical vapor deposition, low pressure gas phase deposition, plasma enhanced chemical vapor deposition, plasma enhanced atomic layer deposition, VHF (Very High Frequency) chemical vapor deposition or initiated chemical vapor deposition (iCVD), and specifically, may be plasma enhanced chemical vapor deposition.

In some embodiments, the base may be a semiconductor substrate including silicon, germanium, silicon-germanium, etc., or a compound semiconductor substrate.

Specifically, the substrate, which is a base, may be disposed inside a chamber. For example, the chamber may be a plasma chamber. The substrate may be disposed on a plate, and the substrate may be heated using the plate. In some embodiments, the plate may also be used as a lower electrode. Through the heating, the temperature of the substrate may be from 0° C. to 500° C., and for example, the temperature of the substrate may be about 230° C. to 300° C.

In some embodiments, source gas and reaction gas may be introduced into the chamber. The source gas may be the silicon precursor, and the reaction gas may be an oxidizing agent. In some embodiments, the reaction gas may be O₂, O₃, N₂O, CO₂ or a combination thereof. Specifically, the silicon precursor may be phase-changed into the source gas, which is a gas, inside a bubbler vessel. In other words, heating the silicon precursor inside the bubbler vessel, the silicon precursor can be phase-changed into the source gas which is in a gaseous state.

Since the silicon precursor can have a relatively high vapor pressure, a relatively large amount of the silicon precursor can be phase-changed into the source gas of a gaseous state under a specific temperature in the bubbler vessel. Therefore, a relatively large amount of the source gas can be easily introduced into the chamber, which enables the deposition process to be performed efficiently and stably.

Furthermore, depending on the process conditions of the deposition process, a relatively large amount of the source gas may be required. In other words, it may be necessary to increase the pressure of the source gas introduced to the chamber. For this, the specific temperature of the bubbler vessel may be increased. Meanwhile, since the silicon precursor may be relatively excellent in thermal stability, its chemical structure may not be easily transformed even under a relatively high specific temperature. Therefore, the low-dielectric film may be formed without process defects.

In some embodiments, the source gas may be introduced into the chamber together with a carrier gas inflowing into the bubbler vessel. In some embodiments, the carrier gas may be an inert gas, for example, helium, neon, argon, krypton, xenon, or radon. In some embodiments, the flow rate of the carrier gas may be from 100 cc/min to 800 cc/min, and the flow rate of the reaction gas (RG) may be from 5 cc/min to 100 cc/min.

During the deposition process, the pressure inside the chamber may be 0.1 Torr to 10 Torr. An upper electrode in the chamber may be connected to a high-frequency generator, and high frequency with a frequency of 5 MHz to 20 MHz and a power of 1 W to 1000 W may be applied to the upper electrode through the high-frequency generator during the deposition process.

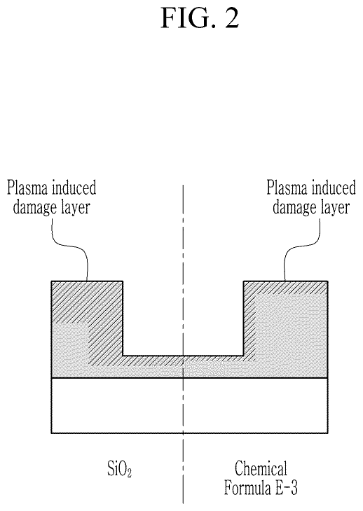

Meanwhile, the low-dielectric film manufacturing method may further include forming a low-dielectric film by depositing the silicon precursor, and then patterning the low-dielectric film for metal deposition. This is a process for forming a metal wire and may be a subsequent process for metal deposition. While prior low-dielectric films may be degraded by plasma resulting in damage (see FIG. 2), the low-dielectric film according to an aspect may minimize plasma-induced damage as described above.

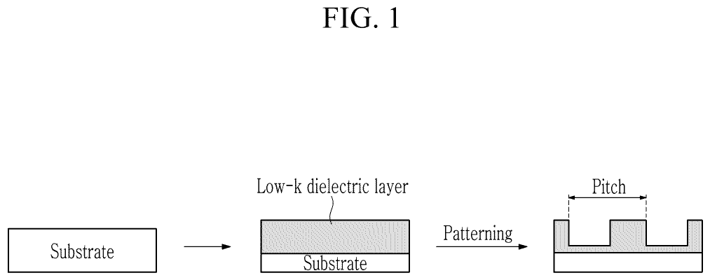

After the patterning for metal deposition, a pitch is formed as shown in FIG. 1, and, in some embodiments, the pitch may be 100 nm or less, for example 90 nm or less, for example 80 nm or less. That is, if the composition according to an aspect is used, a low-dielectric film with excellent plasma resistance even in a small pitch can be formed.

For example, the silicon precursor may contain at least one of the following chemical formula E-1 to chemical formula E-8.

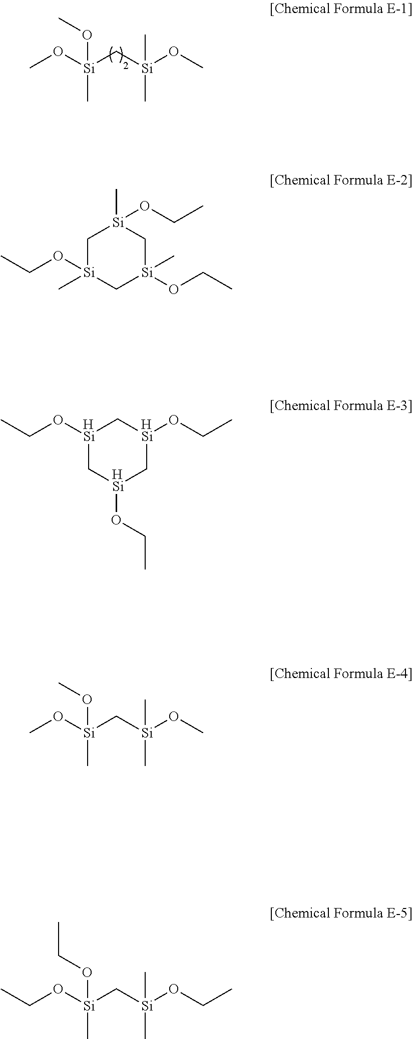

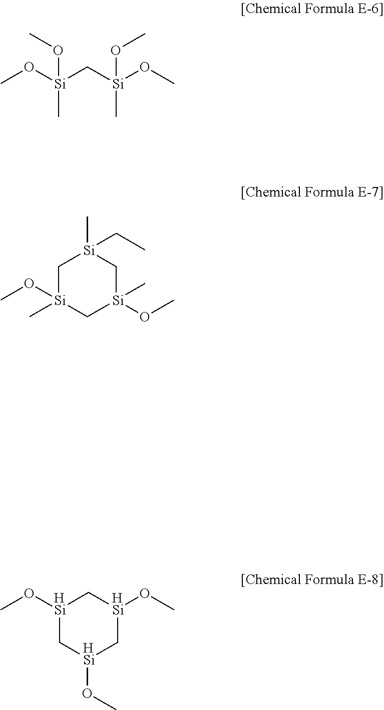

Although embodiments have been described above, the invention is not limited to the embodiments described above, various additions, omissions, substitutions, and modifications may be made. Additionally, it is possible to form other embodiments by combining elements of different embodiments.

Hereinafter, various experiments using a composition improving metal adhesion for semiconductor processes according to an embodiment will be described. The experiments described below do not limit the present disclosure.

### EMBODIMENT

Manufacturing a low-dielectric thin film

### Embodiment 1

A low-dielectric thin film was deposited using a precursor represented by chemical formula E-1 in a conventional plasma-enhanced chemical vapor deposition (PECVD) device which uses the plasma-enhanced chemical vapor deposition (PECVD) method.

The substrate on which the low-dielectric thin film was to be formed was a silicon substrate, and the silicon substrate was transported into the deposition chamber and maintained at a constant temperature of 260° C.

A bubbler type canister, which was made of stainless steel and filled with a precursor represented by the chemical formula E-1, was maintained at a temperature of 80° C. so that the vapor pressure of the precursor was constant. The gasified precursor was introduced into the chamber with helium gas as a carrier gas and deposited on the silicon substrate.

Specifically, the silicon substrate was maintained at 260° C., and the precursor represented by the chemical formula E-1 was filled into a stainless steel bubbler vessel and maintained at 80° C. The process pressure was fixed at 5.5 torr, and the plasma power was applied at 350 W.

The thickness of the deposited thin film was measured using an ellipsometer (UV Spectroscopic Ellipsometer, Elli-SEU-am12, Ellipso technology), the formation of the low-dielectric thin film was analyzed using an infrared spectrophotometer (Fourier transform infrared, VERTEX 70v, Bruker), and the composition of the low-deposition thin film was analyzed using an X-ray photoelectron spectrometer (X-ray Photoelectron Spectrometer, K-Alpha+, ThermoFisher Scientific). Additionally, the dielectric constant was measured using a mercury probe (Hg probe, 802B-150, MDC), and the elasticity coefficient was measured using a nanoindenter (Nanoindentation Test System, iNano Nanoindenter, KLA-Tencor). The result is shown in Table 1.

The ratio of *—Si—C—Si—* bond unit to *—Si—O—* bond unit (*—Si—C—Si—* bond unit/*—Si—O—* bond unit) was calculated by measuring the areas of Si—C—Si peak and Si—O peak in the FTIR plot and then converting “Si—C—Si peak area/Si—O peak area” into a percentage, and presented in the following Table 1 as *—Si—C—Si—* bond unit/*—Si—O—* bond unit ratio [%]. The wavenumber range (x-axis) defining each peak is as follows.
*Si—O peak: 930-1235
*Si—C—Si peak: 1350-1380

Meanwhile, PID(Å) was measured by intentionally damaging the low-dielectric film by subsequent plasma treatment, then removing the damaged portion by wet etching and quantifying the thickness of the removed portion as the degree of damage by plasma, and is shown in Table 1. The conditions of the plasma treatment are as follows. After plasma treatment, wet etching was performed in 200:1 DHF for 30 seconds.
Temp. [° C.]: 350
Time [sec]: 12
RF Power [W]: 800
N₂ flow [sccm]: 700
NH₃ flow [sccm]: 1750
Pressure [torr]: 2.4
Spacing [mm]: 25

### Embodiment 2

Except that the precursor represented by chemical formula E-2 is used instead of the precursor represented by chemical formula E-1, other parameters are the same as embodiment 1.

### Embodiment 3

Except that the precursor represented by chemical formula E-3 was used instead of the precursor represented by chemical formula E-1, and was filled into a stainless steel bubbler vessel and maintained at 25° C. instead of 80° C., other parameters are the same as the embodiment 1.

### Embodiment 4

Except that the precursor represented by chemical formula E-4 is used instead of the precursor represented by chemical formula E-1, other parameters are the same as embodiment 1.

### Embodiment 5

Except that the precursor represented by chemical formula E-5 is used instead of the precursor represented by chemical formula E-1, other parameters are the same as embodiment 1.

### Embodiment 6

Except that the precursor represented by chemical formula E-6 is used instead of the precursor represented by chemical formula E-1, other parameters are the same as embodiment 1.

### Embodiment 7

Except that the precursor represented by chemical formula E-7 is used instead of the precursor represented by chemical formula E-1, other parameters are the same as embodiment 1.

### Embodiment 8

Except that the precursor represented by chemical formula E-8 is used instead of the precursor represented by chemical formula E-1, other parameters are the same as embodiment 1.

### Comparative Example 1

Except that the silicon substrate was maintained at 260° C., a precursor represented by formula C-1, instead of the precursor represented by chemical formula E-1, was filled in a stainless steel bubbler vessel and maintained at −5° C., process pressure was fixed at 5.5 torr, and the plasma power was applied at 250 W, other parameters are the same as embodiment 1.

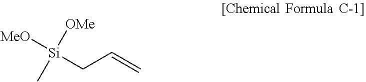

### Comparative Example 2

Except that the precursor represented by chemical formula C-2 was used instead of the precursor represented by chemical formula E-1, other parameters are the same as embodiment 1.

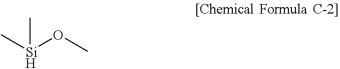

### Comparative Example 3

Except that the precursor represented by formula C-3 was used instead of the precursor represented by chemical formula E-1, others are the same as embodiment 1.

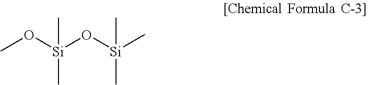

TABLE 1

| | carbon | Si—C—Si/ | | elasticity | |
|---|---|---|---|---|---|
| | content | Si—O | dielectric | coefficient | PID |
| | (%) | (%) | constant | (Gpa) | (Å) |
| Comparative | 30.1 | 0.063 | 2.79 | 13.51 | 135 |
| Example 1 | | | | | |
| Comparative | 25.3 | 0.021 | 2.85 | 9.85 | 140 |
| Example 2 | | | | | |
| Comparative | 27.2 | 0.039 | 2.83 | 8.67 | 180 |
| Example 3 | | | | | |
| Embodiment 1 | 34.0 | 0.135 | 2.92 | 12.83 | 129 |
| Embodiment 2 | 33.3 | 0.146 | 2.72 | 14.22 | 51 |
| Embodiment 3 | 36.8 | 0.155 | 2.81 | 13.10 | 36 |
| Embodiment 4 | 34.2 | 0.127 | 2.89 | 11.54 | 131 |
| Embodiment 5 | 34.8 | 0.128 | 2.93 | 11.71 | 133 |
| Embodiment 6 | 34.2 | 0.115 | 2.74 | 11.08 | 126 |
| Embodiment 7 | 32.7 | 0.146 | 2.75 | 14.06 | 44 |
| Embodiment 8 | 36.0 | 0.155 | 2.75 | 13.08 | 31 |

As shown in Table 1, in cases of dielectric layers according to embodiments of the present disclosure (Embodiment 1 to Embodiment 8), the carbon content, the ratio of *—Si—C—Si—* bonds to *—Si—O—* bonds, the dielectric constant, and the elasticity coefficient are all high, and the PID value is low, so it can be confirmed that the low dielectric characteristics and mechanical strength are the best, the degradation during the wiring forming process can be minimized, and the parasitic capacitance occurring between wirings can be effectively reduced.

Although the embodiments of the present disclosure have been described in detail above, the scope of the present disclosure is not limited thereto, and various modifications and improvements can be made by those skilled in the art using the basic concept of the present disclosure defined in the following claims, and they fall within the scope of the present disclosure.

What is claimed is:

1. A composition for forming a low-dielectric film comprising:
a silicon precursor comprising a *—Si—C—Si—* bond,
wherein the low-dielectric film has a ratio of a *—Si—C—Si—* bond unit/*—Si—O—* bond unit ratio of 0.1 to 0.8.

2. The composition for forming a low-dielectric film of claim 1, wherein
the silicon precursor is represented by formula 1 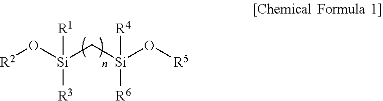
wherein:
each of R¹, R³, R⁴ and R⁶ is independently hydrogen atom, substituted or unsubstituted C1 to C20 alkyl group, substituted or unsubstituted C1 to C20 alkoxy group, substituted or unsubstituted C3 to C20 cycloalkyl group, substituted or unsubstituted C2 to C20 alkenyl group, substituted or unsubstituted C2 to C20 alkynyl group, substituted or unsubstituted C3 to C20 cycloalkenyl group, substituted or unsubstituted C5 to C20 cycloalkynyl group, substituted or unsubstituted C6 to C20 aryl group or substituted or unsubstituted C6 to C20 aryloxy group,
each of R² and R⁵ is independently substituted or unsubstituted C1 to C20 alkyl group, substituted or unsubstituted C3 to C20 cycloalkyl group, substituted or unsubstituted C2 to C20 alkenyl group, substituted or unsubstituted C2 to C20 alkynyl group, substituted or unsubstituted C3 to C20 cycloalkenyl group or substituted or unsubstituted C6 to C20 aryl group, and
n is an integer from 1 to 4.

3. The composition for forming a low-dielectric film of claim 1, wherein
the silicon precursor is represented by formula 2: 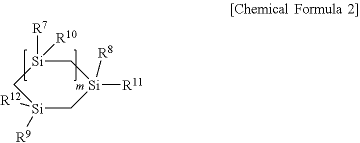
wherein:
each of R⁷ to R¹² is independently hydrogen atom, substituted or unsubstituted C1 to C20 alkyl group, substituted or unsubstituted C1 to C20 alkoxy group, substituted or unsubstituted C3 to C20 cycloalkyl group, substituted or unsubstituted C2 to C20 alkenyl group, substituted or unsubstituted C2 to C20 alkynyl group, substituted or unsubstituted C3 to C20 cycloalkenyl group, substituted or unsubstituted C6 to C20 aryl group or substituted or unsubstituted C6 to C20 aryloxy group, and
m is an integer from 1 to 5.

4. The composition for forming a low-dielectric film of claim 2, wherein
at least one of R¹ to R³ is a substituted or unsubstituted C1 to C20 alkoxy group.

5. The composition for forming a low-dielectric film of claim 4, wherein
R¹ is a substituted or unsubstituted C1 to C20 alkoxy group,
R² to R⁶ are, respectively and independently substituted or unsubstituted C1 to C20 alkyl group, and
n is 1.

6. The composition for forming a low-dielectric film of claim 3, wherein
R¹⁰ to R¹² are respectively and independently substituted or unsubstituted C1 to C20 alkoxy group.

7. The composition for forming a low-dielectric film of claim 6, wherein
R⁷ to R⁹ are respectively and independently hydrogen atom or substituted or unsubstituted C1 to C20 alkyl group, and
m is 1.

8. A low-dielectric film comprising silicon precursor comprising
*—Si—C—Si—* bonding,
wherein a ratio of *—Si—C—Si—* bond unit to *—Si—O—* bond unit in the low-dielectric film is 0.1 to 0.8.

9. The low-dielectric film of claim 8, wherein
a carbon content in the low-dielectric film is 10 at % to 50 at %.

10. The low-dielectric film of claim 8, wherein
a ratio of *—Si—C—Si—* bond unit to *—Si—O—* bond unit of the low-dielectric film is 0.1 to 0.2.

11. The low-dielectric film of claim 8, wherein
the low-dielectric film has a dielectric constant of 2.5 or more and 3 or less.

12. The low-dielectric film of claim 8, wherein
the low-dielectric film has an elasticity coefficient of 8 Gpa to 15 Gpa.

13. The low-dielectric film of claim 8, further comprising pores.

14. A low-dielectric film manufacturing method comprising:
preparing a base; and
depositing a silicon precursor comprising *—Si—C—Si—* bonds on the base to form a low-dielectric film,
wherein a ratio of *—Si—C—Si—* bond unit to *—Si—O—* bond unit in the low-dielectric film is 0.1 to 0.8.

15. The low-dielectric film manufacturing method of claim 14, wherein
the ratio of *—Si—C—Si—* bond unit to *—Si—O—* bond unit of the low-dielectric film is 0.1 to 0.2.

16. The low-dielectric film manufacturing method of claim 14, wherein
the depositing the silicon precursor is performed by atomic layer deposition, metal-organic chemical vapor deposition, low pressure vapor deposition, plasma enhanced chemical vapor deposition, plasma enhanced atomic layer deposition, VHF (Very High Frequency) chemical vapor deposition, or initiated chemical vapor deposition (iCVD).

17. The low-dielectric film manufacturing method of claim 16, wherein
the depositing the low-dielectric film is performed by the plasma-enhanced chemical vapor deposition method.

18. The low-dielectric film manufacturing method of claim 14, further comprising:
patterning the low-dielectric film for metal deposition.

19. The low-dielectric film manufacturing method of claim 18, wherein
a pitch formed after the patterning is less than 100 nm.

20. The low-dielectric film manufacturing method of claim 14, wherein
the silicon precursor comprises at least one of the following chemical formula E-1 to chemical formula E-8: [chemical structure]
